(19) United States
(12) Patent Application Publication
(10) Pub. No.: US 2018/0236691 A1
(43) Pub. Date: Aug. 23, 2018

(54) CUTTING BLADE AND CUTTING APPARATUS

(71) Applicant: DISCO CORPORATION, Tokyo (JP)

(72) Inventors: Suguru Hiraiwa, Tokyo (JP); Kazuhiro Yamamoto, Tokyo (JP); Takeshi Hayashi, Tokyo (JP); Tomoatsu Kobayashi, Tokyo (JP)

(21) Appl. No.: 15/898,903

(22) Filed: Feb. 19, 2018

(30) Foreign Application Priority Data
Feb. 17, 2017 (JP) 2017-027712

(51) Int. Cl. B28D 5/00; H01L 21/67; H01L 21/78

(52) U.S. Cl. CPC B28D 5/0011; B28D 5/0094; H01L 29/1608; H01L 21/67092; H01L 21/78; B28D 5/0076

(57) ABSTRACT

Disclosed herein is an electroformed cutting blade having a cutting edge containing super abrasive grains. The cutting edge further contains filler particles formed of silicon-based organic material.

### BACKGROUND OF THE INVENTION

### Field of the Invention

The present invention relates to a cutting blade for cutting a workpiece such as a semiconductor wafer and also to a cutting apparatus using this cutting blade.

### Description of the Related Art

A workpiece such as a semiconductor wafer having a plurality of devices such as integrated circuits (ICs) and large-scale integrations (LSIs) formed on the front side is divided into individual device chips by using a cutting apparatus having a rotatable cutting blade (see Japanese Patent Laid-open No. 2009-119559, for example). The plural devices are formed in a plurality of separate regions defined by a plurality of division lines previously set on the front side of the workpiece. The device chips obtained by dividing the workpiece are used in various electronic equipment. In the cutting apparatus, the cutting blade is rotated at a high speed and fed into the workpiece held on a chuck table. Further, the chuck table is fed to thereby cut the workpiece along each division line.

### SUMMARY OF THE INVENTION

However, in the case that the workpiece to be cut by the cutting blade is a wafer formed of a hard brittle material such as SiC (silicon carbide) and sapphire, the following problem may arise. When the rotational speed of the cutting blade or the feed speed of the workpiece is increased in cutting the workpiece, i.e., when a processing speed to the workpiece is increased in cutting the workpiece, there is a possibility that chipping having a size greater than an allowable value may be generated on the edge of each device chip divided from the wafer or burning may occur on a dicing tape because of a rise in load current value on a spindle mounting the cutting blade thereon. Accordingly, a reduction in processing quality of each device chip is unavoidable. To cope with this problem, the processing speed to the workpiece must be suppressed in the prior art. As a result, a processing efficiency is reduced.

It is therefore an object of the present invention to provide a cutting blade which can cut a workpiece in the condition where the processing efficiency is increased and the generation of chipping is suppressed.

It is another object of the present invention to provide a cutting apparatus using this cutting blade.

In accordance with an aspect of the present invention, there is provided an electroformed cutting blade having a cutting edge containing super abrasive grains, in which the cutting edge further contains filler particles formed of silicone-based organic material.

Preferably, the content of the filler particles in the cutting edge is set in the range of 5 vol % to less than 40 vol %. Preferably, the particle size of the filler particles is set in the range of 1 to 10 μm.

In accordance with another aspect of the present invention, there is provided a cutting apparatus including a chuck table for holding a workpiece; and cutting means having a rotatable cutting blade for cutting the workpiece held on the chuck table; the cutting blade being an electroformed cutting blade having a cutting edge containing super abrasive grains, the cutting edge further containing filler particles formed of silicone-based organic material.

In the electroformed cutting blade according to the present invention, the filler particles of silicone-based organic material are contained in the cutting edge. Accordingly, even when a processing speed to the workpiece is increased in cutting the workpiece by using the electroformed cutting blade, the generation of chipping on the workpiece can be suppressed in contrast to a conventional cutting blade. The reason why the above effect can be achieved by the electroformed cutting blade according to the present invention is considered to be due to the following factor found out by the present inventor.

The possible factor contributing to the suppression of the generation of chipping on the workpiece is that an ability to retain a cutting water on the surface of the cutting edge can be improved owing to the fact that the filler particles of silicone-based organic material are dispersively contained in the cutting edge. That is, during the cutting operation of cutting the workpiece by using the electroformed cutting blade, the cutting water is supplied to a contact position between the cutting edge and the workpiece, thereby cooling the cutting edge at the contact position and removing cutting dust generated from the workpiece. When the ability to retain the cutting water on the surface of the cutting edge is improved, the cutting water can be well supplied to the contact position between the cutting edge and the workpiece and to its peripheral area. As a result, the cutting dust can be allowed to flow together with the cutting water in the form of a water film, so that the cutting dust can be efficiently removed. Further, the amount of cutting water to be supplied to the contact position between the cutting edge and the workpiece can be increased, so that the cutting edge can be efficiently cooled by the cutting water.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a cutting apparatus using an electroformed cutting blade according to a preferred embodiment of the present invention;

FIG. 2 is a perspective view depicting a manner of fixing a mount flange to a spindle;

FIG. 3 is a perspective view depicting a manner of fixing the electroformed cutting blade through the mount flange to the spindle;

FIG. 4 is a perspective view depicting a condition that the electroformed cutting blade is fixed through the mount flange to the spindle;

FIG. 5 is an exploded perspective view of a cutting unit having the electroformed cutting blade;

FIG. 6 is a perspective view of the cutting unit having the electroformed cutting blade;

FIG. 7 is a vertical sectional view schematically depicting a manufacturing apparatus for the electroformed cutting blade;

FIG. 8 is a sectional view of the electroformed cutting blade formed on a base in the manufacturing apparatus depicted in FIG. 7;

FIG. 9 is a sectional view of the electroformed cutting blade separated from the base;

FIG. 10 is a graph depicting the relation between the feed speed of a workpiece and the maximum value for the size of chipping generated on the front side of the workpiece in the case of using an electroformed cutting blade in Example 1 and an electroformed cutting blade in Comparison 1;

FIG. 11 is a graph similar to FIG. 10, in the case of using an electroformed cutting blade in Example 2 and an electroformed cutting blade in Comparison 2;

FIG. 12 is a graph depicting the relation between a total cut distance in the workpiece cut along the division lines by the electroformed cutting blade in Example 2 and the maximum value for the size of chipping generated on the front side of the workpiece; and

FIG. 13 is a graph depicting the relation between a total cut distance in the workpiece cut along the division lines by the electroformed cutting blade in Example 2 and a load current value on the spindle mounting the electroformed cutting blade thereon.

### DETAILED DESCRIPTION OF THE PREFERRED EMBODIMENT

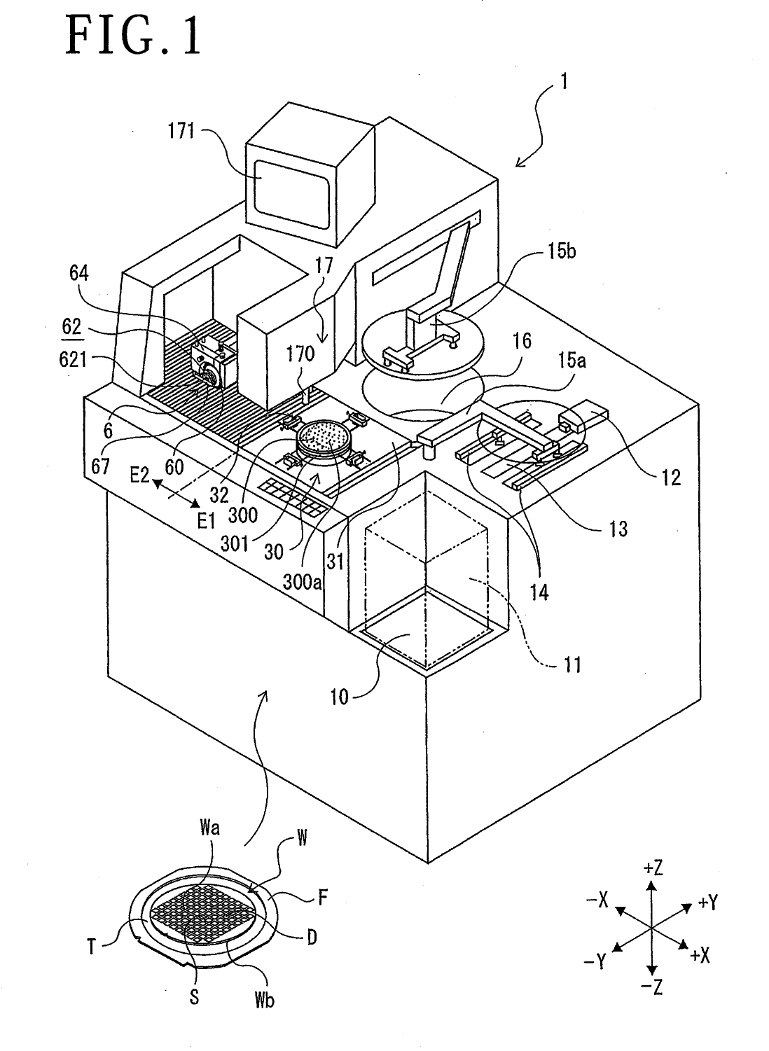

Referring to FIG. 1, a cutting apparatus 1 is depicted. The cutting apparatus 1 includes a chuck table 30 for holding a workpiece W and cutting means (cutting unit) 6 for cutting the workpiece W held on the chuck table 30. The chuck table 30 is movable in the X direction by X moving means or work feeding means (not depicted). The cutting means 6 is movable in the Y direction by Y moving means or indexing means (not depicted) and also movable in the Z direction by Z moving means or cutter feeding means (not depicted). The X direction represents the +X direction indicated by an arrow +X or the −X direction indicated by an arrow −X. The Y direction represents the +Y direction indicated by an arrow +Y or the −Y direction indicated by an arrow −Y. The Z direction represents the +Z direction indicated by an arrow +Z or the −Z direction indicated by an arrow −Z.

An elevating mechanism 10 is provided at a front end portion (−Y side) of the cutting apparatus 1 so as to be movable in the Z direction, i.e., both in the +Z direction and in the −Z direction. A wafer cassette 11 is placed on the upper surface of the elevating mechanism 10. A plurality of workpieces W each supported through a dicing tape T to an annular frame F are stored in the wafer cassette 11. Handling means 12 is provided on the rear side (+Y side) of the wafer cassette 11 to take one of the workpieces W out of the wafer cassette 11 before cutting or to return the workpiece W into the wafer cassette 11 after cutting. A temporary placement area 13 for temporarily placing the workpiece W before cutting or after cutting is provided between the wafer cassette 11 and the handling means 12. In the temporary placement area 13, there is provided positioning means 14 for positioning the workpiece W temporarily placed.

First transfer means 15a is provided in the vicinity of the temporary placement area 13 to transfer the workpiece W between the chuck table 30 and the temporary placement area 13. The first transfer means 15a is so configured as to hold the workpiece W under suction, whereby the workpiece W to be cut is held under suction and then transferred from the temporary placement area 13 to the chuck table 30.

Cleaning means 16 for cleaning the workpiece W after cutting is provided in the vicinity of the first transfer means 15a. Further, there is provided above the cleaning means 16 second transfer means 15b for transferring the workpiece W from the chuck table 30 to the cleaning means 16 after cutting. The second transfer means 15b is also configured so as to hold the workpiece W under suction.

The chuck table 30 depicted in FIG. 1 is circular in outside shape, and it includes a suction holding portion 300 for holding the workpiece W under suction and a frame member 301 for supporting the suction holding portion 300. The suction holding portion 300 has a holding surface 300a as an exposed surface communicating with a vacuum source (not depicted), and the workpiece W is held on the holding surface 300a under suction. The chuck table 30 is surrounded by a cover 31. The chuck table 30 is rotatable about its axis extending in the Z direction by any rotating means (not depicted). Further, four clamps 32 for clamping the annular frame F are provided around the chuck table 30 so as to be uniformly spaced in the circumferential direction of the chuck table 30.

The chuck table 30 is reciprocatively movable in the X direction by the X moving means or work feeding means (not depicted) provided under the cover 31, between a standby area E1 where the workpiece W is held on the chuck table 30 before cutting or is unheld from the chuck table 30 after cutting and a cutting area E2 where the workpiece W is cut by the cutting means 6. There is provided above a moving path of the chuck table 30 alignment means 17 for detecting division lines S formed on the front side Wa of the workpiece W, and the division lines S are to be cut by the cutting means 6. The alignment means 17 includes imaging means 170 for imaging the front side Wa of the workpiece W and can detect the division lines S to be cut according to an image obtained by the imaging means 170. The cutting means 6 for cutting the workpiece W held on the chuck table 30 is provided in the cutting area E2 in the vicinity of the alignment means 17. The cutting means 6 and the alignment means 17 are integrated and they are movable together in the Y direction and the Z direction. The alignment means 17 further includes display means 171 for displaying the image obtained by the imaging means 170.

The cutting means 6 depicted in FIG. 1 includes a spindle unit 62 having a spindle 621 rotatable about its axis, an electroformed cutting blade 60 fixedly mounted on the spindle 621, a blade cover 64 for covering the electroformed cutting blade 60, and a pair of cutting water nozzles 67 (see FIG. 5) for supplying a cutting water to the electroformed cutting blade 60.

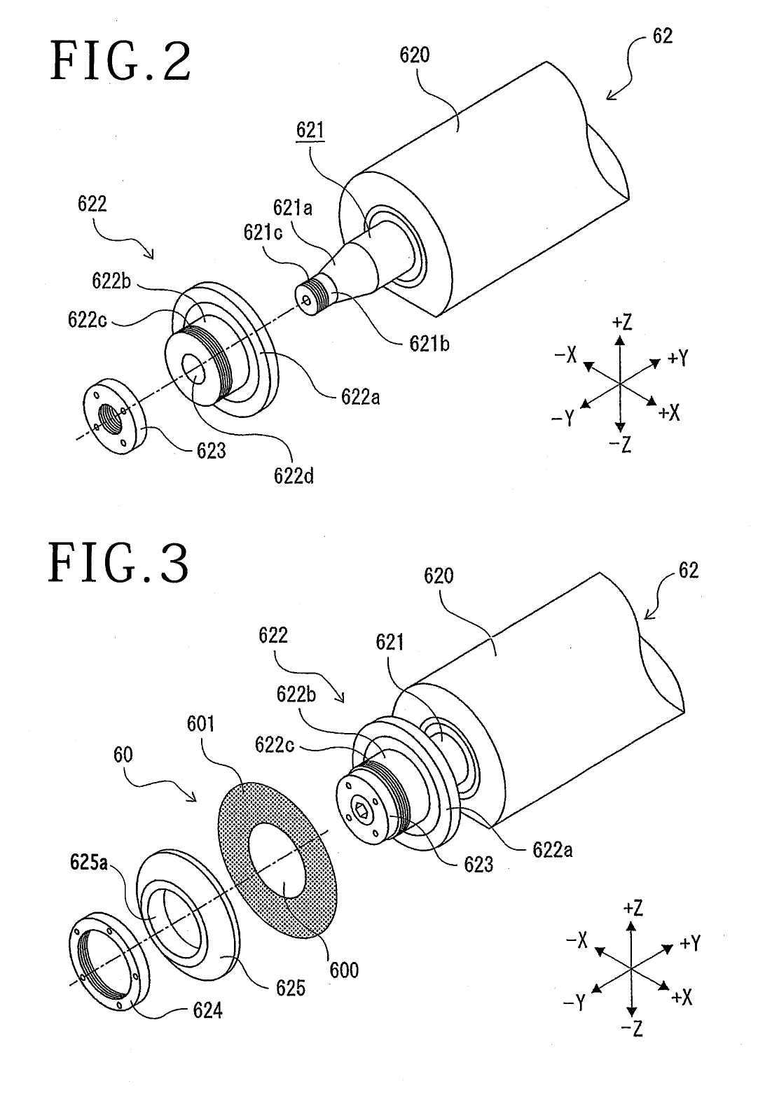

As depicted in FIG. 2, the spindle unit 62 includes a spindle housing 620 for rotatably supporting the spindle 621. The spindle 621 is rotatably driven by a motor (not depicted). The axis of the spindle 621 extends in the Y direction. A front end portion of the spindle 621 projects from the spindle housing 620 in the −Y direction. This projecting portion of the spindle 621 has a tapered portion 621a tapered toward its front end on the −Y side and a small-diameter portion 621b extending from the front end of the tapered portion 621a in the −Y direction. The small-diameter portion 621b has an external thread 621c on the outer circumferential surface.

As depicted in FIG. 2, a mount flange 622 is detachably mounted on the projecting portion of the spindle 621. The mount flange 622 includes a flange portion 622a and a boss portion 622b projecting from the flange portion 622a in its thickness direction (Y direction), the boss portion 622b being smaller in diameter than the flange portion 622a. The boss portion 622b has an external thread 622c on the outer circumferential surface. The mount flange 622 has a central mounting hole (through hole) 622d extending in the thickness direction, i.e., in the axial direction. The mounting hole 622d of the mount flange 622 is adapted to be fitted to the tapered portion 621a of the spindle 621. After the tapered portion 621a of the spindle 621 is inserted into the mounting hole 622d of the mount flange 622 in the condition where the small-diameter portion 621b of the spindle 621 projects from the boss portion 622b, a nut 623 is threadedly engaged with the external thread 621c of the small-diameter portion 621b. Accordingly, by tightening the nut 623, the mount flange 622 is fixedly mounted on the front end portion of the spindle 621.

As depicted in FIG. 3, the electroformed cutting blade 60 is a washer type hubless blade having an annular shape. The electroformed cutting blade 60 has a central mounting hole 600 and an annular cutting edge 601 formed around the mounting hole 600.

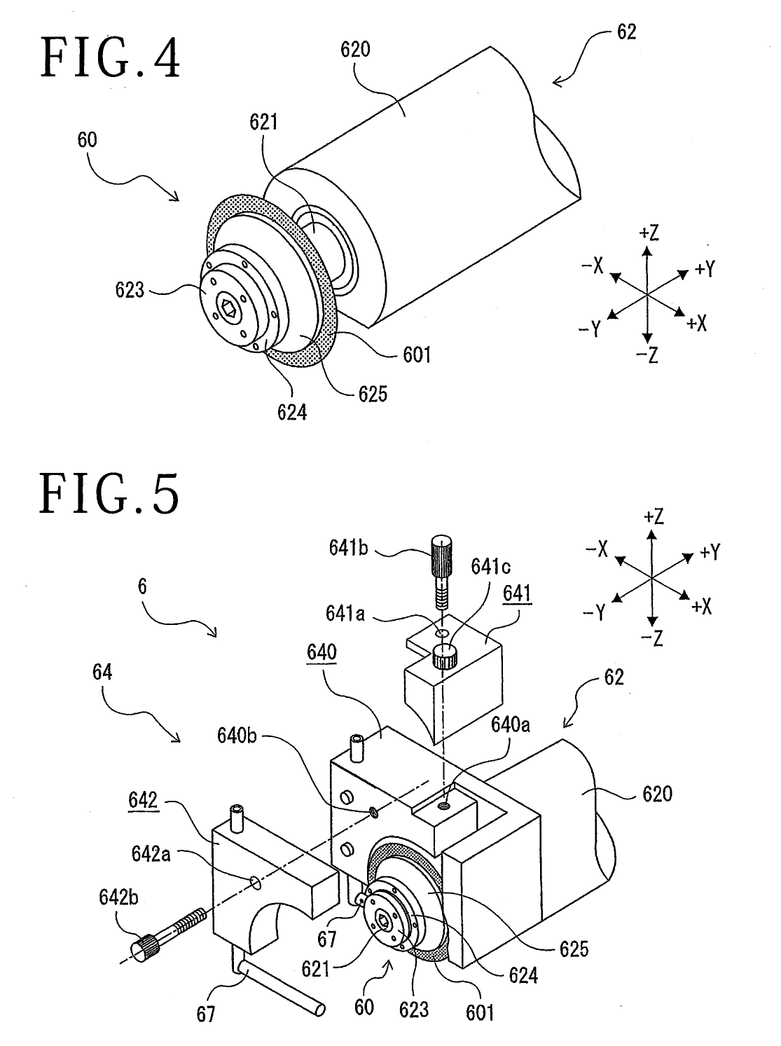

After the boss portion 622b of the mount flange 622 is inserted through the mounting hole 600 of the electroformed cutting blade 60, a detachable flange 625 is mounted on the boss portion 622b of the mount flange 622. The detachable flange 625 has a central engaging hole (through hole) 625a through which the boss portion 622b is adapted to be inserted. That is, the engaging hole 625a of the detachable flange 625 is adapted to engage the boss portion 622b. After the detachable flange 625 is mounted on the boss portion 622b, a ring nut 624 is threadedly engaged with the external thread 622c of the boss portion 622b and tightened to thereby axially press the detachable flange 625 toward the flange portion 622a of the mount flange 622. Accordingly, as depicted in FIG. 4, the electroformed cutting blade 60 is tightly held between the detachable flange 625 and the mount flange 622 (not depicted in FIG. 4) from the opposite sides in the Y direction. Thus, the electroformed cutting blade 60 is firmly mounted through the mount flange 622 to the spindle 621. The spindle 621 is rotationally driven by the motor (not depicted) to thereby rotate the electroformed cutting blade 60 at a high speed.

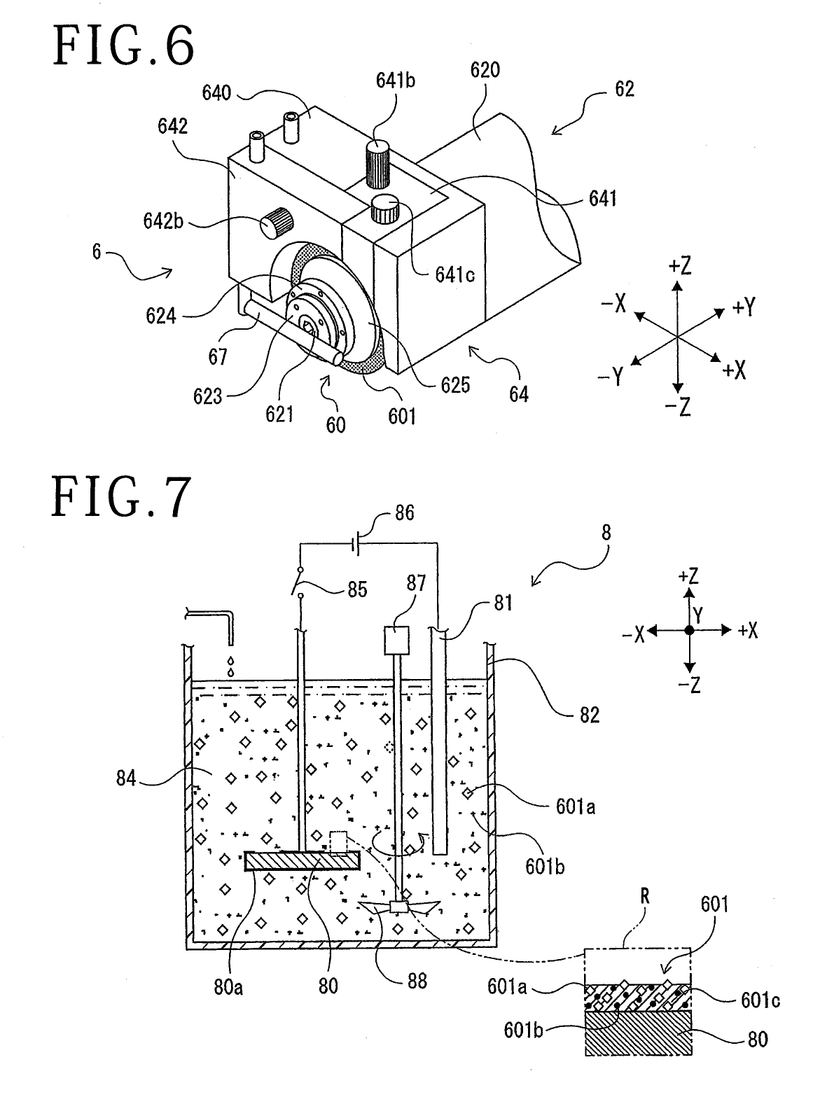

As depicted in FIGS. 5 and 6, the blade cover 64 for covering the electroformed cutting blade 60 includes a base portion 640 fixed to the spindle housing 620 of the spindle unit 62, a blade detection block 641 mounted on the base portion 640, and a detachable cover 642 mounted on the base portion 640. The base portion 640 is fixed to the spindle housing 620 of the spindle unit 62 in such a manner as to cover the electroformed cutting blade 60 from the +Z side. As depicted in FIG. 5, the blade detection block 641 has a through hole 641a for insertion of a screw 641b, and the base portion 640 has a tapped hole 640a on the upper surface. The screw 641b is inserted through the through hole 641a of the blade detection block 641 and screwed into the tapped hole 640a of the base portion 640 to thereby mount the blade detection block 641 to the base portion 640 from the +Z side. The blade detection block 641 is provided with a blade sensor (not depicted) composed of a light emitting device and a photodetector. The position of the blade sensor in the Z direction is adjustable by an adjusting screw 641c. The blade sensor functions to detect the condition of the cutting edge 601 of the electroformed cutting blade 60.

The detachable cover 642 has a through hole 642a for insertion of a screw 642b, and the base portion 640 has a tapped hole 640b on one side surface on the −Y side. The screw 642b is inserted through the through hole 642a of the detachable cover 642 and screwed into the tapped hole 640b of the base portion 640 to thereby mount the detachable cover 642 to the base portion 640 from the −Y side.

The pair of cutting water nozzles 67 are vertically movably mounted on the blade cover 64, so as to supply a cutting water to a work point where the electroformed cutting blade 60 comes into contact with the workpiece W. Each cutting water nozzle 67 has an L-shape as viewed from the −Y side. The two cutting water nozzles 67 are arranged so as to interpose the electroformed cutting blade 60 from the opposite sides in the Y direction. Each cutting water nozzle 67 has a plurality of nozzle holes (not depicted) directed to the cutting edge 601 of the electroformed cutting blade 60. These nozzle holes are in communication with a cutting water source (not depicted).

The electroformed cutting blade 60 may be manufactured by using an electroformed cutting blade manufacturing apparatus 8 depicted in FIG. 7. The electroformed cutting blade manufacturing apparatus 8 includes a liquid bath 82 for storing an electrolytic solution (nickel plating solution) 84 such as nickel sulfate solution, nickel nitrate solution, and nickel sulfamate solution. Diamond abrasive grains 601a are previously mixed in the electrolytic solution 84 stored in the liquid bath 82. On the other hand, filler particles 601b formed of silicone-based organic material (polyorgano silsesquioxane) are previously mixed in a predetermined surface active agent solution and dispersed in this surface active agent solution. This surface active agent solution containing the filler particles 601b in the dispersed condition is next mixed into the electrolytic solution 84 stored in the liquid bath 82, and the electrolytic solution 84 thus containing the filler particles 601b is next stirred.

Thereafter, a base 80 on which an electroformed cutting blade is to be formed by electrodeposition and an electrolytic metal 81 such as nickel are immersed in the electrolytic solution 84. The base 80 is a disk-shaped member formed of metal such as stainless steel and aluminum. A mask 80a having a shape corresponding to the shape of the electroformed cutting blade to be formed is previously formed on the surface of the base 80. More specifically, the mask 80a has a shape such that the annular hubless type electroformed cutting blade 60 depicted in FIG. 6 can be formed. The base 80 is connected through a switch 85 to the minus terminal (negative electrode) of a DC power source 86. On the other hand, the electrolytic metal 81 is connected to the plus terminal (positive electrode) of the direct current (DC) power source 86. The switch 85 may be interposed between the electrolytic metal 81 and the DC power source 86.

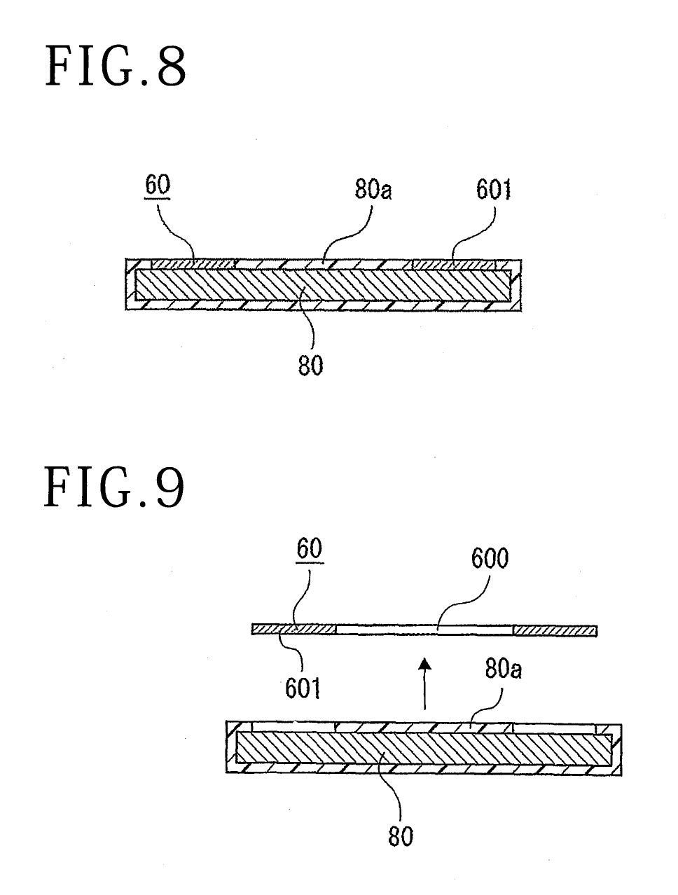

The electrolytic solution 84 is stirred by operating a rotational drive source 87 such as a motor to rotate a fan 88 immersed in the electrolytic solution 84. In this condition, the switch 85 is turned on to pass a DC current in the electrolytic solution 84 in the condition where the base 80 functions as a cathode and the electrolytic metal 81 functions as an anode. Accordingly, the diamond abrasive grains 601a and the filler particles 601b mixed in the electrolytic solution 84 are sedimented, so that the diamond abrasive grains 601a, the filler particles 601b, and a plating layer (electrodeposition layer) 601c (see FIG. 7) are deposited on the surface of the base 80 in an area not covered with the mask 80a. As depicted in an enlarged part R in FIG. 7, the diamond abrasive grains 601a and the filler particles 601b can be substantially uniformly dispersed in the electrodeposition layer 601c containing nickel, thus forming the cutting edge 601. When a predetermined thickness of the cutting edge 601 formed on the base 80 is reached, the base 80 is drawn from the electrolytic solution 84 as depicted in FIG. 8.

Thereafter, the electroformed cutting blade 60 is separated from the base 80 as depicted in FIG. 9. Furthermore, the inner and outer circumferences of the annular cutting blade 60 are processed by a grinding apparatus or the like to obtain desired accurate inner and outer diameters of the annular cutting blade 60. Thus, the washer type electroformed cutting blade 60 depicted in FIGS. 3 and 9 is completed.

There will now be described the operation of the cutting apparatus 1 depicted in FIG. 1 in the case of cutting the workpiece W by using the electroformed cutting blade 60 included in the cutting apparatus 1.

The workpiece W to be cut by the cutting apparatus 1 is an optical device wafer, for example. The optical device wafer is formed from an SiC substrate having a thickness of 250 μm, for example. The front side Wa of the workpiece W is partitioned into a plurality of separate regions by the crossing division lines S, and a plurality of optical devices D such as light emitting diodes (LEDs) and laser diodes (LDs) are formed in the respective separate regions. The back side Wb of the wafer W is attached to the adhesive surface of the dicing tape T at its central portion, and the peripheral portion of the dicing tape T is attached to the annular frame F. Thus, the workpiece W is supported through the dicing tape T to the annular frame F. Accordingly, the workpiece W can be handled by using the annular frame F.

First, the handling means 12 is operated to take one of the plural workpieces W out of the wafer cassette 11 to the temporary placement area 13, each workpiece W being supported through the dicing tape T to the annular frame F. In the temporary placement area 13, the workpiece W is positioned by the positioning means 14. Thereafter, the workpiece W is held under suction by the first transfer means 15a and then transferred from the temporary placement area 13 to the holding surface 300a of the chuck table 30. Thereafter, the annular frame F is clamped by the clamps 32, and the workpiece W is held under suction through the dicing tape T on the holding surface 300a. Thus, the workpiece W is held by the chuck table 30.

After holding the workpiece W on the chuck table 30, the X moving means (not depicted) is operated to move the chuck table 30 holding the workpiece W in the −X direction from the standby area E1 to the cutting area E2. During the movement of the chuck table 30, the imaging means 170 is operated to image the front side Wa of the workpiece W, thereby detecting the division lines S to be cut. At the same time, the Y moving means (not depicted) is operated to move the cutting means 6 in the Y direction, thereby aligning the electroformed cutting blade 60 with a target one of the division lines S extending in a first direction.

Thereafter, the X moving means (not depicted) is operated again to further move the chuck table 30 in the −X direction at a predetermined feed speed. At the same time, the Z moving means (not depicted) is operated to lower the cutting means 6 in the −Z direction down to a vertical position where the lowermost end of the electroformed cutting blade 60 passes through the workpiece W to reach a depth of 30 μm in the dicing tape T, for example. Further, the spindle 621 is rotated at a high speed by the motor (not depicted) to thereby rotate the electroformed cutting blade 60 fixed to the spindle 621 at the high speed. Accordingly, the electroformed cutting blade 60 rotating at the high speed is relatively fed along the target division line S, thereby cutting the workpiece W along the target division line S. During this cutting operation, a cutting water is supplied from the cutting water nozzles 67 to the contact position between the cutting edge 601 of the electroformed cutting blade 60 and the target division line S of the workpiece W, thereby cooling and cleaning the contact position.

When the workpiece W is fed to reach a predetermined position in the X direction where the cutting of the target division line S by the electroformed cutting blade 60 is ended, the feeding of the workpiece W by the X moving means is once stopped and the Z moving means is operated to raise the electroformed cutting blade 60 from the workpiece W. Thereafter, the chuck table 30 is moved in the +X direction by the X moving means until reaching the original position where the cutting of the target division line S by the electroformed cutting blade 60 has been started. Thereafter, the electroformed cutting blade 60 is sequentially indexed in the Y direction by the pitch of the division lines S to similarly cut the workpiece W along all of the other division lines S extending in the first direction. Thereafter, the chuck table 30 is rotated 90 degrees by the rotating means (not depicted) to similarly perform the cutting operation along the other division lines S extending in a second direction perpendicular to the first direction. Thus, the workpiece W is cut along all of the crossing division lines S extending in the first and second directions perpendicular to each other.

### Example 1

In Example 1, an electroformed cutting blade was manufactured under the following conditions. Diamond abrasive grains having a grain size of #1700 as super abrasive grains were used as the diamond abrasive grains 601a depicted in FIG. 7, and filler particles of silicone-based organic material (polyorgano silsesquioxane) having an average particle size of 5 μm were used as the filler particles 601b depicted in FIG. 7. The diamond abrasive grains 601a and the filler particles 601b were bonded by the electrodeposition layer 601c of nickel plating to form the cutting edge 601 depicted in FIG. 6. The content of the filler particles 601b in the cutting edge 601 was set to 35 vol %, and the content of the diamond abrasive grains 601a in the cutting edge 601 was set to 7.5 vol %. The electroformed cutting blade thus manufactured will be hereinafter referred to as “electroformed cutting blade in Example 1.”

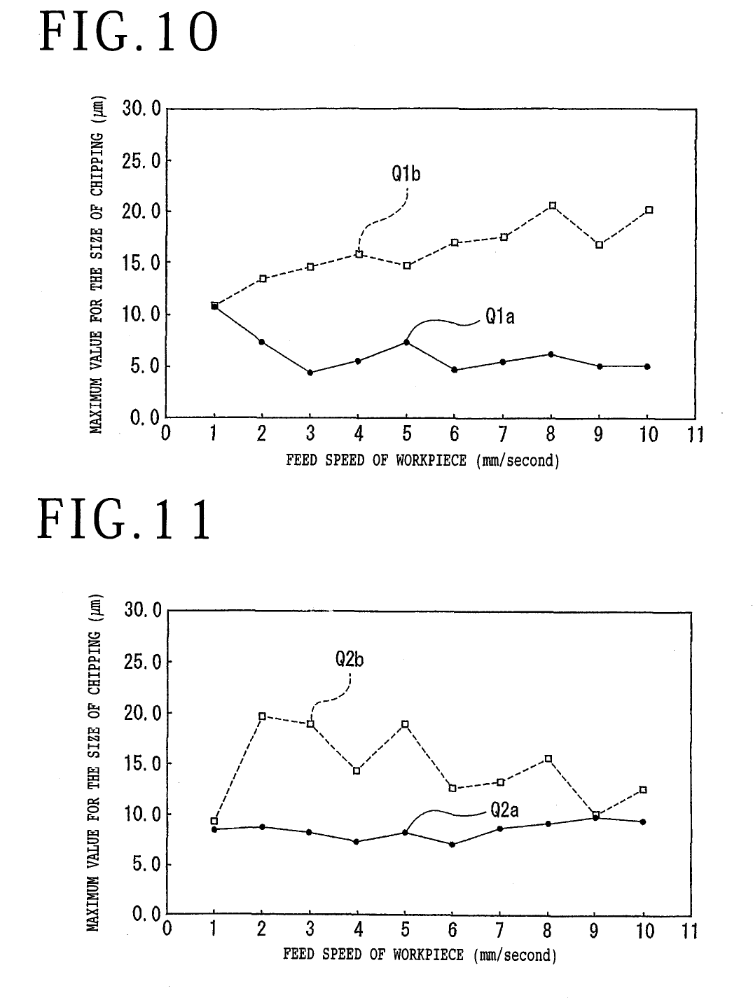

By using the electroformed cutting blade in Example 1, the workpiece W was cut along the division lines S in the condition where the feed speed of the chuck table 30 was stepwise increased by 1 mm/second every time the cutting along each division line S was finished and a cutting water was supplied to a contact position between the cutting edge 601 and the workpiece W. Further, the cutting edge 601 was not dressed during the cutting operation. The depth of cut in the workpiece W by the electroformed cutting blade in Example 1 was set in such a manner that the lowermost end of the cutting blade 601 has passed through the workpiece W to reach a depth of 30 μm in the dicing tape T. The rotational speed of the electroformed cutting blade in Example 1 was set to approximately 14000 rpm. The feed speed of the chuck table 30 in cutting the first division line S was set to 1 mm/second. In FIG. 10, a line graph Q1a is indicated by dots and solid lines, in which the line graph Q1a indicates the relation between the feed speed of the workpiece W held on the chuck table 30 in cutting the workpiece W by using the electroformed cutting blade in Example 1 and the maximum value (μm) for the size of chipping generated on the front side Wa of the workpiece W. The line graph Q1a is terminated at the time when the workpiece W was cut along the tenth division line S, i.e., at the time when the feed speed of the chuck table 30 was increased to 10 mm/second.

As apparent from the line graph Q1a depicted in FIG. 10, the maximum value (μm) for the size of chipping generated on the front side Wa of the workpiece W falls within the range of approximately 5 to 7 μm. That is, the following result was confirmed in Example 1. Even when the feed speed of the chuck table 30 is increased to increase the processing speed for the workpiece W, there is no possibility that chipping having a size greater than an allowable value may be generated on the front side Wa of the workpiece W.

### (Comparison 1)

In Comparison 1, an electroformed cutting blade similar to the electroformed cutting blade in Example 1 except the filler particles 601b were not contained in the cutting edge 601 was used to cut the workpiece W under the same conditions as those in Example 1. This electroformed cutting blade not containing the filler particles 601b will be hereinafter referred to as “electroformed cutting blade in Comparison 1.” In FIG. 10, a line graph Q1b is indicated by rectangles and broken lines, in which the line graph Q1b indicates the relation between the feed speed of the workpiece W in cutting the workpiece W by using the electroformed cutting blade in Comparison 1 and the maximum value (μm) for the size of chipping generated on the front side Wa of the workpiece W.

As apparent from the line graph Q1b depicted in FIG. 10, the maximum value (μm) for the size of chipping generated on the front side Wa of the workpiece W increases with an increase in the feed speed. Further, it was confirmed that chipping having a size greater than an allowable value was generated on the front side Wa of the workpiece W. That is, the size of chipping in Comparison 1 is greater than that in Example 1.

### Example 2

In Example 2, an electroformed cutting blade was manufactured under the following conditions. Diamond abrasive grains having a grain size of #1700 as super abrasive grains were used as the diamond abrasive grains 601a depicted in FIG. 7, and filler particles of silicone-based organic material (polyorgano silsesquioxane) having an average particle size of 5 μm were used as the filler particles 601b depicted in FIG. 7. The diamond abrasive grains 601a and the filler particles 601b were bonded by the electrodeposition layer 601c of nickel plating to form the cutting edge 601 depicted in FIG. 6. The content of the filler particles 601b in the cutting edge 601 was set to 23 vol %, and the content of the diamond abrasive grains 601a in the cutting edge 601 was set to 15 vol %. The electroformed cutting blade thus manufactured will be hereinafter referred to as “electroformed cutting blade in Example 2.”

By using the electroformed cutting blade in Example 2, the workpiece W was cut along the division lines S in the condition where the feed speed of the chuck table 30 was stepwise increased by 1 mm/second every time the cutting along each division line S was finished and a cutting water was supplied to a contact position between the cutting edge 601 and the workpiece W. Further, the cutting edge 601 was not dressed during the cutting operation. The depth of cut in the workpiece W by the electroformed cutting blade in Example 2 was set in such a manner that the lowermost end of the cutting blade 601 has passed through the workpiece W to reach a depth of 30 μm in the dicing tape T. The rotational speed of the electroformed cutting blade in Example 2 was set to approximately 14000 rpm. The feed speed of the chuck table 30 in cutting the first division line S was set to 1 mm/second. In FIG. 11, a line graph Q2a is indicated by dots and solid lines, in which the line graph Q2a indicates the relation between the feed speed of the workpiece W held on the chuck table 30 in cutting the workpiece W by using the electroformed cutting blade in Example 2 and the maximum value (μm) for the size of chipping generated on the front side Wa of the workpiece W. The line graph Q2a is terminated at the time when the workpiece W was cut along the tenth division line S, i.e., at the time when the feed speed of the chuck table 30 was increased to 10 mm/second.

As apparent from the line graph Q2a depicted in FIG. 11, the maximum value (μm) for the size of chipping generated on the front side Wa of the workpiece W falls within the range of approximately 7 to 10 μm without large variations. That is, the following result was confirmed in Example 2. Even when the feed speed of the chuck table 30 is increased to increase the processing speed for the workpiece W, there is no possibility that chipping having a size greater than an allowable value may be generated on the front side Wa of the workpiece W.

### (Comparison 2)

In Comparison 2, an electroformed cutting blade similar to the electroformed cutting blade in Example 2 except the filler particles 601b were not contained in the cutting edge 601 was used to cut the workpiece W under the same conditions as those in Example 2. This electroformed cutting blade not containing the filler particles 601b will be hereinafter referred to as “electroformed cutting blade in Comparison 2.” In FIG. 11, a line graph Q2b is indicated by rectangles and broken lines, in which the line graph Q2b indicates the relation between the feed speed of the workpiece W in cutting the workpiece W by using the electroformed cutting blade in Comparison 2 and the maximum value (μm) for the size of chipping generated on the front side Wa of the workpiece W.

As apparent from the line graph Q2b depicted in FIG. 11, the maximum value (μm) for the size of chipping generated on the front side Wa of the workpiece W largely changes in the range of approximately 10.0 to 20.0 μm with an increase in the feed speed. That is, the maximum value (μm) for the size of chipping is not stable. Further, it was confirmed that chipping having a size greater than an allowable value was generated on the front side Wa of the workpiece W. That is, the size of chipping in Comparison 2 is greater than that in Example 2.

### (Relation Between a Total Cut Distance and the Size of Chipping in the Case of Cutting the Workpiece by Using the Electroformed Cutting Blade in Example 2)

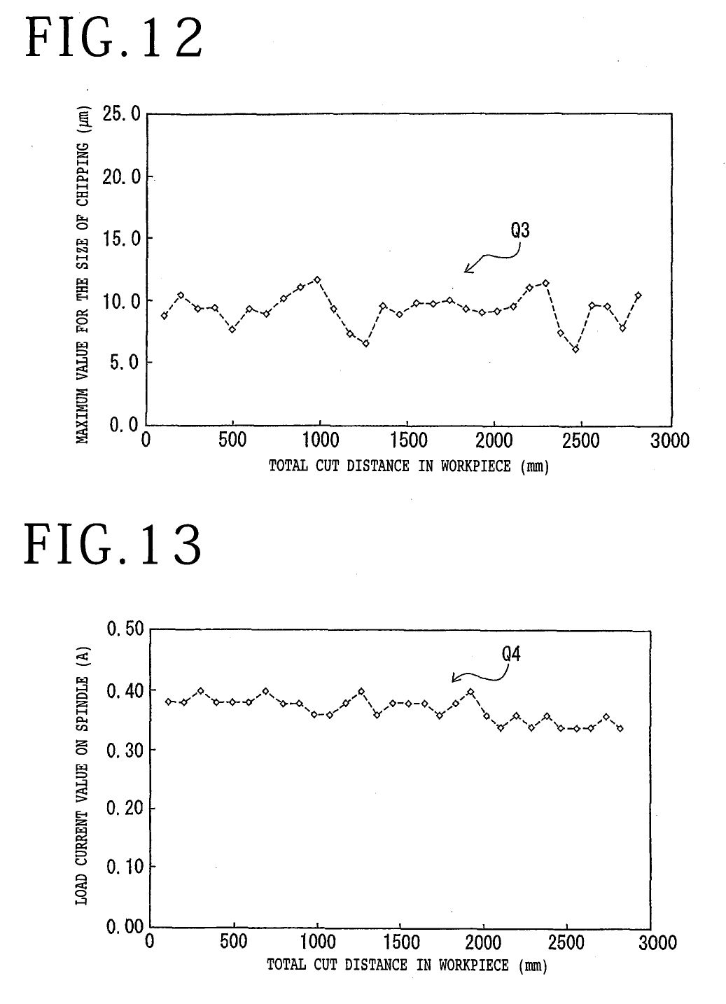

The workpiece W was cut by using the electroformed cutting blade in Example 2 in the condition where the feed speed of the chuck table 30 in cutting the workpiece W along all of the division lines S was set constant and the depth of cut in the workpiece W by the electroformed cutting blade in Example 2 was set in such a manner that the lowermost end of the cutting edge 601 has passed through the workpiece W to reach a depth of 30 μm in the dicing tape T. The rotational speed of the electroformed cutting blade in Example 2 was set to approximately 14000 rpm. In FIG. 12, a line graph Q3 is indicated by rhombuses and broken lines, in which the line graph Q3 indicates the relation between a total cut distance (mm) and the maximum value (μm) for the size of chipping generated on the front side Wa of the workpiece W in cutting the workpiece W along the division lines S by using the electroformed cutting blade in Example 2. In FIG. 12, the horizontal axis represents the total cut distance, and the vertical axis represents the maximum value for the size of chipping. Further, in FIG. 13, a line graph Q4 is indicated by rhombuses and broken lines, in which the line graph Q4 indicates the relation between a total cut distance (mm) and a load current value (A) on the spindle 621 mounting the electroformed cutting blade in Example 2 in cutting the workpiece W along the division lines S by using the electroformed cutting blade in Example 2. In FIG. 13, the horizontal axis represents the total cut distance, and the vertical axis represents the load current value.

As apparent from the line graph Q3 depicted in FIG. 12, the maximum value (μm) for the size of chipping generated on the front side Wa of the workpiece W falls within the range of approximately 7 to 12 μm even when the number of division lines S cut by the electroformed cutting blade in Example 2 is increased, i.e., even when the total cut distance in the workpiece W cut by the electroformed cutting blade in Example 2 is increased. That is, it was confirmed that even when the total cut distance in the workpiece W is increased, there is no possibility that chipping having a size greater than an allowable value may be generated on the front side Wa of the workpiece W.

### (Relation Between a Total Cut Distance and a Load Current on the Spindle in the Case of Cutting the Workpiece by Using the Electroformed Cutting Blade in Example 2)

As apparent from the line graph Q4 depicted in FIG. 13, the load current value on the spindle 621 gently rises and lowers in the range of approximately 0.36 to 0.41 A even when the number of division lines S cut by the electroformed cutting blade in Example 2 is increased, i.e., even when the total cut distance in the workpiece W cut by the electroformed cutting blade in Example 2 is increased. That is, it was confirmed that even when the total cut distance in the workpiece W is increased, there is no possibility that the load current value on the spindle 621 may become greater than an allowable value and continue to rise.

In the electroformed cutting blade in Example 1 and the electroformed cutting blade in Example 2, the filler particles 601b of silicone-based organic material are contained in the cutting edge 601. Accordingly, as depicted in FIGS. 10 and 11, even when the feed speed of the workpiece W is increased in cutting the workpiece W, the generation of chipping having a size greater than an allowable value on the front side Wa of the workpiece W can be suppressed in contrast to the electroformed cutting blade in Comparison 1 and the electroformed cutting blade in Comparison 2. Further, as apparent from the line graph Q3 depicted in FIG. 12, the generation of chipping having a size greater than an allowable value can be prevented by using the electroformed cutting blade in Example 2 even when the cut distance in the workpiece W is accumulated. The reason why the above effect can be achieved by the electroformed cutting blade in Example 1 and the electroformed cutting blade in Example 2 is considered to be due to the following factor found out by the present inventor.

The possible factor is that an ability to retain the cutting water on the surface of the cutting edge can be improved owing to the fact that the filler particles 601b of silicone-based organic material are dispersively contained in the cutting edge of each of the electroformed cutting blades in Examples 1 and 2. That is, when the ability to retain the cutting water on the surface of the cutting edge is improved, the cutting water can be well supplied to the contact position between the cutting edge and the workpiece W and to its peripheral area. As a result, cutting dust can be allowed to flow together with the cutting water in the form of a water film, so that the cutting dust can be efficiently removed. Further, the amount of cutting water to be supplied to the contact position between the cutting edge and the workpiece W can be increased, so that the cutting edge can be efficiently cooled by the cutting water. As a result, it is considered that the generation of chipping on the workpiece W can be suppressed as indicated by the line graph Q1a in FIG. 10, for example.

Further, as indicated by the line graph Q4 in FIG. 13, the load current value on the spindle 621 does not become greater than an allowable value even when the total cut distance in the workpiece W is increased in the case of using the electroformed cutting blade in Example 2. Accordingly, it is possible to prevent the possibility that the electroformed cutting blade in Example 2 may be broken because of an abnormal rise in the load current value on the spindle 621. Further, it is also possible to prevent the possibility that the workpiece W may be damaged by a spark produced between the electroformed cutting blade in Example 2 and the workpiece W. Thus, there is no possibility that the cutting of the workpiece W may become unstable.

As in the electroformed cutting blades in Examples 1 and 2, the content of the filler particles 601b in the cutting edge is preferably set in the range of 5 vol % to less than 40 vol %, more preferably, in the range of 10 to 30 vol %. If the content of the filler particles 601b in the cutting edge is too high (e.g., 50 vol %), the diamond abrasive grains 601a may fall off regardless of self sharpening such that an old part of the diamond abrasive grains 601a is removed by the cutting operation and a new part of the diamond abrasive grains 601a is exposed to the surface of the cutting edge. As a result, the cutting performance of the electroformed cutting blade is reduced. However, when the content of the filler particles 601b in the cutting edge is in the range of 5 vol % to less than 40 vol %, the above problem can be avoided.

Further, the cutting means 6 in the cutting apparatus 1 according to the present invention includes the electroformed cutting blade characterized in that the filler particles 601b are dispersively contained in the cutting edge 601. Accordingly, a plurality of workpieces W can be cut by the cutting means 6 in the condition where chipping having a size greater than an allowable value is not generated on each workpiece W and there is no possibility that the cutting of each workpiece W may become unstable due to a rise in load current value on the spindle 621.

The electroformed cutting blade according to the present invention is not limited to the electroformed cutting blade in Example 1 and the electroformed cutting blade in Example 2. Further, the configurations of the cutting apparatus 1 and the workpiece W depicted in FIG. 1 are merely illustrative and they may be suitably modified within the scope where the effects of the present invention can be exhibited.

For example, the shape of the workpiece W is not especially limited. Further, the kind of the workpiece W is not limited to an optical device wafer formed of SiC. The workpiece W may be a semiconductor wafer formed of Si. Further, the workpiece W may be a wafer composed of a substrate and a low-k film formed on the substrate, in which the low-k film is formed by stacking low-permittivity insulators and metal foils such as copper and aluminum in an intertwined manner.

The electroformed cutting blade according to the present invention is not limited to an annular washer type (hubless type) electroformed cutting blade as in Example 1, but may be a hubtype electroformed cutting blade having a hub formed of aluminum, for example, and a cutting edge projecting radially outward from the outer circumference of the hub.

The grain size of the diamond abrasive grains contained in the cutting edge of the electroformed cutting blade according to the present invention is preferably set in the range of #360 to #4000 as in the electroformed cutting blades in Examples 1 and 2. Further, the super abrasive grains contained in the electroformed cutting blade according to the present invention are not limited to diamond abrasive grains, but may be cubic boron nitride (CBN) abrasive grains. Further, the content of the diamond abrasive grains in the cutting edge is preferably set in the range of 3.75 to 22.5 vol %, more preferably, in the range of 7.5 to 22.5 vol %. That is, when the content of the diamond abrasive grains 601a in the cutting edge 601 falls within the range of 7.5 to 22.5 vol % as in the electroformed cutting blades in Examples 1 and 2, the cutting performance of the electroformed cutting blade can be sufficiently maintained.

The particle size of the filler particles 601b contained in the electroformed cutting blade according to the present invention is not limited to 5 μm as in the electroformed cutting blades in Examples 1 and 2, but may be set in the range of 1 to 10 μm. Further, the silicone-based organic material forming the filler particles 601b is not limited to polyorgano silsesquioxane, but may be any other silicone-based organic materials such as polydimethyl siloxane (dimethicone), polysiloxane, polysilane, polysilazane, polycarbosilane, methyl vinyl silicone rubber, vinyl phenyl silicone rubber, and methyl vinyl phenyl silicone rubber.

Further, the hardness (HV) of the electrodeposition layer 601c in the electroformed cutting blade according to the present invention is preferably set to 450 HV or more. When the hardness of the electrodeposition layer 601c in the electroformed cutting blade 60 is 450 HV or more, there is a low possibility that the electroformed cutting blade may be bent during the cutting operation. Accordingly, it is possible to prevent the possibility that the electroformed cutting blade may meander on the workpiece W during the cutting operation.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. An electroformed cutting blade having a cutting edge containing super abrasive grains, wherein said cutting edge further contains filler particles formed of silicone-based organic material.

2. The electroformed cutting blade according to claim 1, wherein the content of said filler particles in said cutting edge is set in the range of 5 vol % to less than 40 vol %.

3. The electroformed cutting blade according to claim 1, wherein the particle size of said filler particles is set in the range of 1 to 10 μm.

4. A cutting apparatus comprising:
a chuck table for holding a workpiece; and
cutting means having a rotatable cutting blade for cutting said workpiece held on said chuck table;
said cutting blade being an electroformed cutting blade having a cutting edge containing super abrasive grains, said cutting edge further containing filler particles formed of silicone-based organic material.
